(19) United States
(12) Patent Application Publication
(10) Pub. No.: US 2019/0361508 A1
(43) Pub. Date: Nov. 28, 2019

(54) TEMPERATURE-BASED DYNAMIC FAN CONTROL

(71) Applicant: Seagate Technology LLC, Cupertino, CA (US)

(72) Inventors: Suresh Reddy Yarragunta, Bangalore (IN); Muthuraj Madasamy, Bangalore (IN); Nitin Kumar Singh, Aligarh (IN); Vineeth Kumar Vasudevan, Bangalore (IN); Vishal Hukumchand Bafna, Pune (IN)

(21) Appl. No.: 15/987,109

(22) Filed: May 23, 2018

(51) Int. Cl. G06F 1/20; G05D 23/19; H05K 7/20; F04D 27/00

(52) U.S. Cl. CPC G06F 1/206; G05D 23/1934; F04D 27/004; H05K 7/20209; H05K 7/20136

(57) ABSTRACT

A system includes an enclosure defining an air flow path having an input end and an output end. A plurality of devices are operatively supported by the enclosure and located proximate the air flow path, each of the devices having at least one operating parameter. A plurality of cooling fans are supported by the enclosure that are configured to cause air to propagate according to the air flow path from the input end to the output end. A plurality of temperature sensors supported by the enclosure are located at a plurality of locations that are proximate the air flow path. A controller is configured to adjust at least one fan speed of the plurality of cooling fans based on individual readings of the plurality of temperature sensors and according to the at least one operating parameter of each of the plurality of devices.

### BACKGROUND

Aspects of the present disclosure relate to monitoring and controlling a plurality of variable-speed cooling fans in a computer system. In high-density computer systems, more than one hundred individual computing devices can individually and together produce a substantial amount of heat during operation. In certain ambient conditions, forced convection airflow caused by cooling fans may include air flow that is too low to allow for air evenness throughout the devices, leading to inaccurate readings for individual devices being cooled.

Existing methods and systems for device cooling typically rely on predetermined cooling fan speeds based on a power draw reading of one or more devices, or a temperature reading taken at the devices. In addition, in some cases, a fan speed RPM floor can be set in order to assure adequate air circulation when fans may be spinning to slowly to fully circulate air. Challenges relate to assuring each device is operating within optimal thermal conditions exist. A particular device's temperature tolerance can be greater than default or universal “safe” limits set on systems with uniform fan speed settings and control. Therefore, for at least these reasons, there is a need for improvements to fan control for use in device cooling schemes.

### SUMMARY

According to a first aspect of the present disclosure, a system is disclosed. According the first aspect, the system includes an enclosure defining an air flow path having an input end and an output end. The system also includes a plurality of devices operatively supported by the enclosure and located proximate the air flow path, each of the devices having at least one operating parameter. The system also includes a plurality of cooling fans supported by the enclosure that are configured to cause air to propagate according to the air flow path from the input end to the output end. The system also includes a plurality of temperature sensors supported by the enclosure that are located at a plurality of locations that are proximate the air flow path. The system also includes a controller configured to adjust at least one fan speed of the plurality of cooling fans based on individual readings of the plurality of temperature sensors and according to the at least one operating parameter of each of the plurality of devices.

According to a second aspect of the present disclosure, a method of controlling a plurality of cooling fans is disclosed. According to the second aspect, the method includes providing a plurality of cooling fans supported by an enclosure that are configured to cause air to propagate according to an air flow path from an input end to an output end. The method also includes operatively connecting the plurality of cooling fans to a controller. The method also includes providing a plurality of devices supported by the enclosure that are located proximate the air flow path, where each of the devices has at least one operating parameter. The method also includes providing a plurality of temperature sensors supported by the enclosure that are located at a plurality of locations that are proximate the air flow path. The method also includes adjusting, using the controller, at least one fan speed of the plurality of cooling fans based on individual readings of the plurality of temperature sensors and according to the at least one operating parameter of each of the plurality of devices.

According to a third aspect of the present disclosure, a computer program product for controlling a plurality of cooling fans is disclosed. According to the first aspect, the computer program product includes a computer-readable storage medium having program code embodied therewith, the program code including g computer-readable program code configured to perform a method. According to the third aspect, the method includes providing a plurality of cooling fans supported by an enclosure that are configured to cause air to propagate according to an air flow path from an input end to an output end. The method also includes operatively connecting the plurality of cooling fans to a controller. The method also includes providing a plurality of devices supported by the enclosure that are located proximate the air flow path, where each of the devices has at least one operating parameter, where a controller loop is utilized to control operation of at least one of the plurality of devices, and where at least one operating parameter is a dynamic power dissipation parameter. The method also includes providing a plurality of temperature sensors supported by the enclosure that are located at a plurality of locations that are proximate the air flow path. The method also includes adjusting, using the controller, at least one fan speed of the plurality of cooling fans based on individual readings of the plurality of temperature sensors and according to the at least one operating parameter of each of the plurality of devices.

### BRIEF DESCRIPTION OF THE DRAWINGS

FIG. 1 a schematic layout of a system is shown in according with various embodiments of the present disclosure.

FIG. 2 is a schematic layout of another high-density computing enclosure including a plurality of devices arranged along an air flow path having an air flow direction, according to various embodiments.

FIG. 3 is a flowchart of a process of controlling cooling fan speed within an enclosure, according to various embodiments.

FIG. 4 is a flowchart of another process of controlling cooling fan speed within an enclosure, according to various embodiments.

FIG. 5 is a graphical representation of maximum device temperatures and corresponding fan speed at various ambient temperature representative of existing cooling fan control schemes.

FIG. 6 shows graphical data of cooling fan schemes of the present disclosure as compared to an example prior art scheme.

FIG. 7 shows example data chart for a variety of devices as they are used in existing schemes.

FIG. 8 shows an example data chart for a variety of devices as they are used in existing schemes, with reference in particular to Network Equipment Building System (NEBS) CPUs.

FIG. 9 shows an example data chart for a new scheme of controlling cooling fans, according to embodiments of the present disclosure.

FIG. 10 shows an example data chart for a single CPU according to various embodiments of the present disclosure.

FIG. 11 is a comparative chart of DTS, Tcase, and VPD for a CPU at various power levels according to the data within the data chart of FIG. 10.

FIG. 12 is a block schematic diagram of a computer system according to embodiments of the present disclosure.

### DETAILED DESCRIPTION

The present disclosure relates to improvements to aspects of cooling fan control for use in computer systems. In more detail, the present disclosure related to using device operating parameters and temperature readings along an air flow path to define a minimum safe speed for use in fan speed control.

This disclosure makes many improvements over the exiting art. Embodiments can operate to change parameters and inputs/outputs within a fan speed control loop based on temperature monitoring of individual devices. This can operate to avoid the power consumption and acoustic issues, described herein. The fan controller manages one or more thermal zones using various temperature sensors. The controller attempts to ensure that the enclosure operates its fans at the minimum revolutions per minute (RPM) required to achieve the recommended target temperature for the zones so that it can balance enclosure cooling with acoustics and power consumption. High density storage such as 4U106 chassis has 106 drives in the system to support high storage application.

Electronics generally operate best in a certain range of environmental temperatures. In particular, overheating can be detrimental to computing electronics. Therefore, there is a desire to cool electronics such that they do not overheat. Oftentimes, cooling is effected through the use of cooling fans in order to bolster convective cooling. Existing fan control methodologies for certain high-density server enclosures can operate sufficiently at certain ambient temperatures, but have difficulties below a certain ambient temperature.

Server or computing high-density enclosures can presently operate sufficiently at an ambient temperature higher than about 15° C. At an ambient temperature above a certain threshold, cooling fans can be automatically set at sufficient speed to drive air through the enclosure. During lower ambient temperature conditions (e.g., less than about 15° C.), which may be optimal for use in devices for use in computers such as data centers, ambient temperatures may be desirably maintained at about 10° C. In such a case, a cooling system controller typically operates to automatically drop to set minimum RPM based on various zone temperatures. However, it has been determined that using existing configurations, devices were operating at temperatures above the devices' thermal operating limits (e.g., operating at a relatively high temperature of 60° C.).

It has been shown that a relationship of a sensed device temperature compared to a temperature sensed at a corresponding backplane and temperatures sensed at sensors located elsewhere can become undesirably erratic at relatively low cooling fan RPMs. This can be due at least in part to the fact that the enclosure air flow resistance is typically significant due at least in part to one or more air flow paths that pass a number of devices to be cooled before exiting the enclosure. The enclosure can houses and support the devices. As a result, it is common that the air of the air flow path (air pushed by the cooling fans through forced convection) reaching a first row of devices (devices located closest to incoming fresh air at cooling fans) are efficiently cooled, whereas a last row of devices (devices located further from the incoming fresh air at cooling fans) becomes problematically stale before exiting the enclosure through exit vents.

Currently this air flow stagnation at low ambient temperature and low cooling fan speed issue is overcome by setting the minimum fan speed for each fan in the enclosure to a set RPM, e.g., 7,000 RPM. The minimum cooling fan speed has typically been set based on a device's maximum thermal stress limit, which may represent one or a number of device operating parameters. In terms of device function, however, a simple maximum allowable temperature may not be a sufficient parameter to assure system functions optimally. A system employing heat-producing devices can employ different workloads than computer-simulated “worst case” workloads. Furthermore, in existing systems per manufacturing standards, a fan speed tolerance of ±10% of the set RPM is common per fan specifications.

A desire of the present disclosure is the permit the devices in a fan-cooled enclosure to operate as efficiently and effectively as possible, while also employing a minimum allowable cooling fan speed within the enclosure. By employing embodiments of the present disclosure, system power consumption can be reduced, including both fan power consumption and device power consumption, acoustics noise can be reduced, and average fan life can be extended. In addition, overheating of the devices and other system components can also be reduced using the control schemes (using a controller) described herein. According to various embodiments disclosed herein, energy saving can be achieved across all AHRAE A2 and A3 temperature ranges.

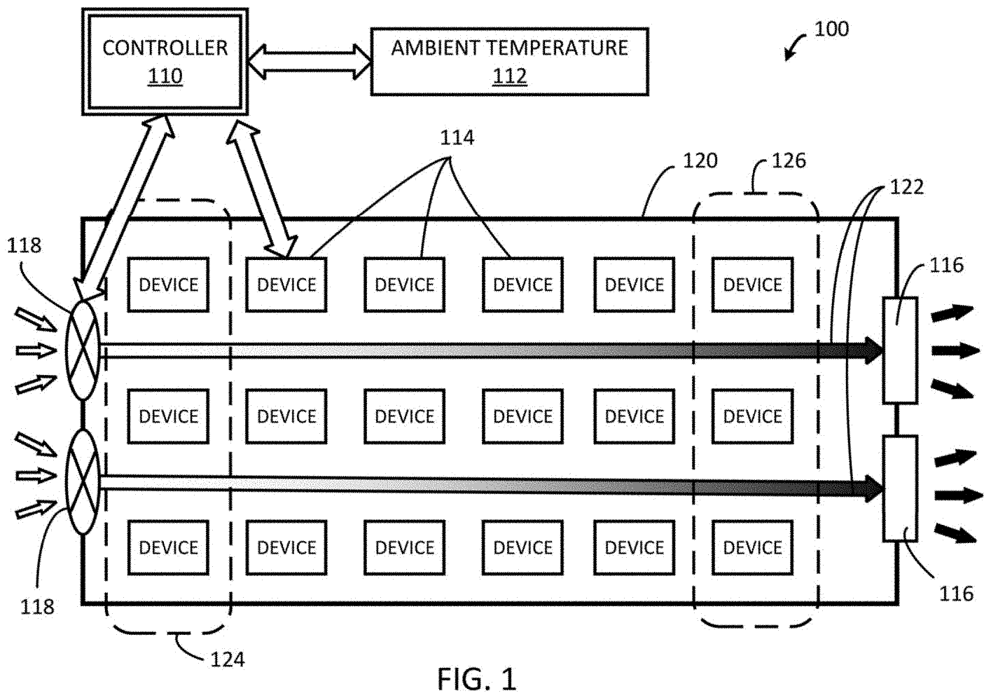

With reference now to FIG. 1, a schematic layout of a system 100 is shown. A plurality of devices 114 are housed and supported by an enclosure 120, and the devices 114 are arranged in rows and columns within the enclosure 120. In the prior art, the last row of devices 126 in the enclosure 120 would suffer from air flow stagnation, i.e., a lack of efficient forced convection. Heat produced by the devices 114 in the enclosure 120 typically then is left with only inefficient heat transfer via natural convection. In a case where the devices 114 are cooled with substantially only natural convection, the devices 114 can often become hot and can exceed the allowable operating temperature limit of each device 114. This can lead to a number of drawbacks, such as system failures, slowdown, and/or damage to devices 114 or related components. Therefore, preset target set values for temperature sensors that may work for forced convection (using cooling fans 118) flow become problematic when applied to a natural convection flow regimes. System 100 improves cooling and system 100 efficiency through improved methods and systems of controlling one or more cooling fans 118.

The devices 114 can be cooled using the one or more cooling fans 118 that can be controlled by controller 110 such that a system 100 operates to send only as much power to the cooling fans 118 as needed by the devices 114 being cooled, while sufficiently cooling the hottest devices 114 that may be located in a last column of devices 126 that is located near an end of an air flow path 122 within the enclosure 120. The controller 110 can be configured to read (or receive) operating parameters at or from each of the plurality of devices 114 and a plurality of temperature sensors (not shown), and selectively operating and controlling the cooling fans 118 at higher or lower fans speeds according to temperature readings at relatively hot areas detected within the system's enclosure 120. The present disclosure can avoid the need to set a minimum overall RPM for each cooling fan of a system 100, and can use the controller 110 to lower an overall or average RPM and cooling fan 118 power consumption.

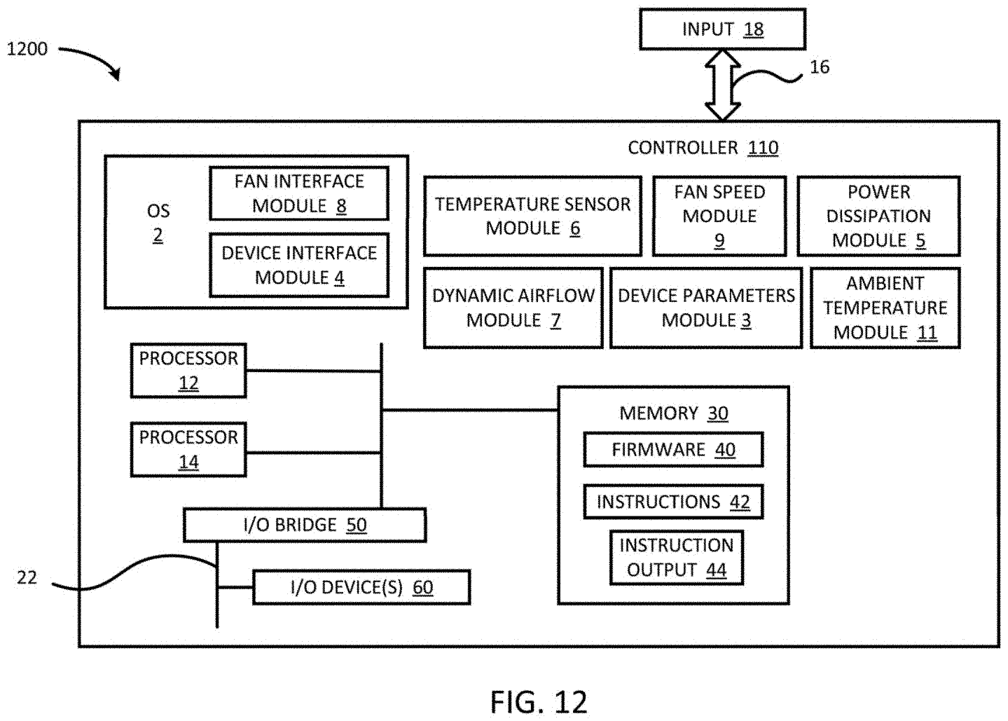

The speed of the fans 120 used to cool the devices can be controlled with a controller 110 (described in greater schematic detail with respect to FIG. 12) operatively connected with one or more temperature sensors (not shown) located within the enclosure 120. Temperature sensors, as used herein, can include digital thermal sensors (DTS). The temperature sensors can include backplane temperature sensors and side plane temperature sensors, in order to receive temperature readings for multiple locations, as may be desirable, according to various device 114 requirements and operating parameters. Devices 114, as used herein can include hard-disk drive (HDD) or central processing unit (CPU), among other heat producing electronic devices.

In system 100 described herein, the plurality of temperature sensors can be positioned within the enclosure 120 at various zones or locations within the air flow path 122 to sense for local and/or ambient (e.g., within the air flow path 122) temperatures. The temperature sensors can be attached to the enclosure 120, the devices 114, or any other location. The temperature sensors can be supported by the enclosure 120 itself, and/or by any components located within the enclosure, such as devices 114, cooling fans 118, exit vents 116, or any other components or features of the enclosure 120. In some embodiments, one or more temperature sensors can also be included within and/or attached to each device 114 itself for a local temperature of the device 114. By controlling the operation of the cooling fans 118 based on the various temperature readings and in conjunction with the device 114 specifications and operating parameters, the cooling fans 118 can be caused to operate at higher or lower rotational speeds, in order to keep the devices 114 sufficiently cooled while simultaneously reducing overcooling due to excessive fan 118 speed or undercooling due to insufficient fan 118 speed.

In order to efficiently thermally manage the plurality of devices 114 (e.g., CPUs, HDDs, among others), the fan speed controller 110 can determine and control an optimal fan speed of one or more cooling fans 118 within an enclosure 120. The enclosure 120 can define the air flow path 122 that includes an air intake at the cooling fans 118, and an air exhaust at the exit vents 116. Utilizing one or more temperature sensors positioned near the devices 114 and supported by the enclosure 120, the fan speed controller 110 can be used to set a minimum cooling fan speed in view of device 114 parameters, such as optimal operating temperature while under load or while idle. Other parameters can include device 114 dynamic power dissipation (DPD) parameters and vital product data (VPD). Dynamic power characteristics, including DPD, can be used for cooling fan 118 speed control at controller 110. VPD can include maximum safe operating temperatures and other thermal related data for each device 114. Furthermore, if DPD is not detected and analyzed by controller 110, the cooling fan 118 speed control could be fixed instead of variable. It therefore can be beneficial to employ DPD during variable-speed cooling fan 118 control, according to various embodiments.

Based on temperature readings, tolerances, and DPD parameters, the disclosed systems and methods are configured to seamlessly work with various devices 114, which can be computing devices, such as drives, chipsets, or processors having varied parameters and heat-related tolerances and nominal operating temperatures.

The controller 110 can also monitor the devices' 114 temperatures to drive and control appropriate fan speeds of the cooling fans 118. The control of cooling fans 118 can be operated independent from other zones, drawers, or server systems, which can be similar to system 100. The controller 110 can use the sensed device 114 temperature to drive the cooling fan 118 speeds within the enclosure 120 apart from and independent of other zones or enclosures. The controller 110 can be configured to monitor a total number of devices 114 present in the enclosure, and can determine the detected temperature of the last row of devices 126 along the air flow path 122 in order to control the cooling fan 118 speed. The controller can control the speed of cooling fans 118 irrespective of device 114 parameters, such as device stressing readings and the number of devices 114 present in the enclosure 120, so that it optimizes performance, e.g., service memory and response time of system 100.

The controller 110 can manage one or more thermal zones with the use of various temperature sensors. The controller 110 can operate to keep the cooling fans 118 associated with the enclosure 120 at a minimum RPM required to achieve the recommended target temperature for the zones and/or devices 114 so that it can balance enclosure 120 cooling with acoustics and power consumption. The present disclosure can support high storage density computing applications.

According to various embodiments, the controller 110 can be used to monitor both the total number of devices 114 (e.g., HDDs or CPUs) present in the system enclosure 120 and the controller 110 can determine a temperature of a last row of devices 114 along the air flow path 122 to control the fan speed and corresponding air flow in the enclosure 120. The control of the fan speed can be accomplished irrespective of device 114 stressing and the number of devices 114 in the enclosure 120 in order to optimize performance, for example, service memory and response time.

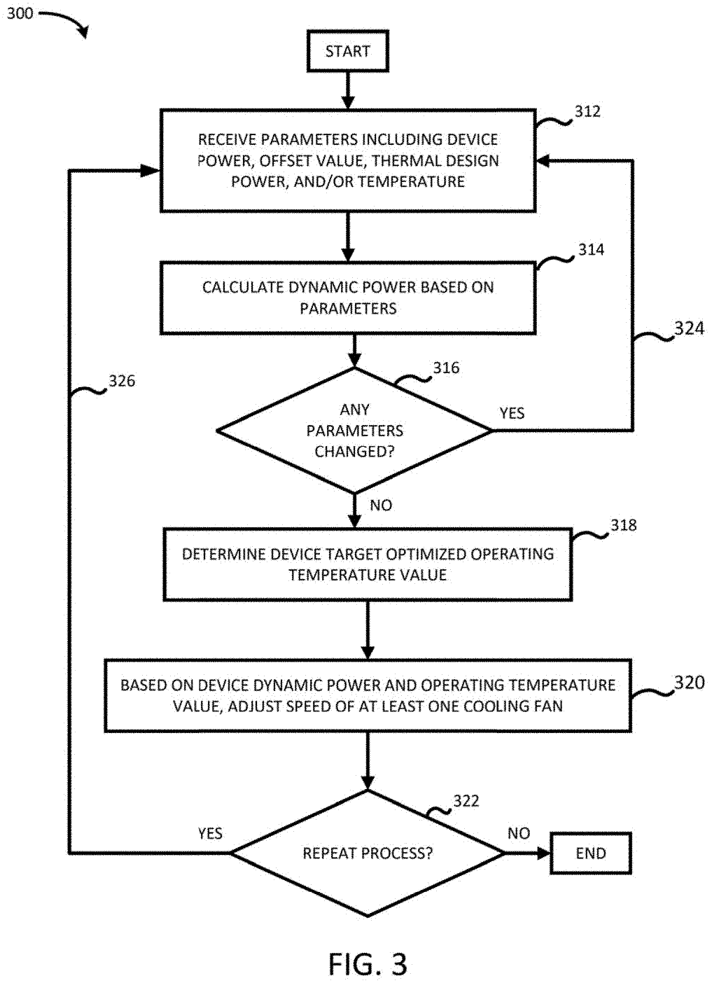

The controller 110 can operate to determine the optimum VPD for device 114 or dynamic power (e.g., for a CPU) as well. Disclosed embodiments can be based on an exponential mathematical function (see, e.g., FIG. 3 and accompanying description) that is used by the controller 110 to drives the fan speed target based on a CPU's (device's) detected temperature (using a digital thermal sensor, for instance), offset and power.

Embodiments of the present disclosure where at least one device is a CPU, provide for fan speed control using the controller 110 that is based on the DPD and temperature reading values of each CPU in order to generate the optimum CPU target temperature value. By using the generated optimum CPU target temperature value, varied CPU types and chipsets such as INTEL Haswell, Broadwell, and Skylake, among others, can be employed seamlessly and be efficiently cooled for preferable operation. In some cases, the controller 110 can provide optimum enclosure 120 cooling by preventing overcooling or undercooling, according to the CPU and enclosure parameters. Using the present disclosure for fan speed control for CPUs can optimize CPU cooling and to resolve various long-term CPU reliability issues related to heat.

For example, device 114 parameters for CPUs include various aspects that can affect CPU performance in a computing system, such as system 100. The storage and computing industry often demands various CPU types and chipsets (e.g., stock-keeping units) to meet customer needs, both in terms of performance and the cost. Each CPU type has its own allowable case temperature limits for long term and short term operations. A single CPU target value or a single set of formulas may not be valid due to different case temperature values for each individual CPU. A CPU is often a key component in a computing system (such as system 100), in part due to high density requirement in the system 100. In existing configuration, a single CPU target temperature value, or a set of operating temperature and parameters were recommended, e.g., as a formula. These operating parameters were often invalid for individual CPUs among many others due to different or unique case temperature values for each CPU.

In other embodiments, at least some devices 114 are instead storage devices, such HDDs. Where devices 114 are HDDs, the present disclosure can be applied to a high-density storage such as a 4U106 chassis, which has 106 HDDs in the chassis. Various devices 114 can each have device parameters unique to the type and model of the device. In yet other embodiments, system 100 can include an enclosure 120 that includes at least some CPUs and at least some HDDs.

According to some embodiments, for example where additional cooling power is beneficial to system 100 operation, exit vents 116 can optionally be replaced with additional cooling fans similar to cooling fans 118, and in some embodiments, cooling fans 118 are replaced with fresh air vents and cooling fans are positioned where exit vents 116 are shown. The air flow path 122 will have a cooler end and a warmer end regardless of where cooling fans 118 are positioned.

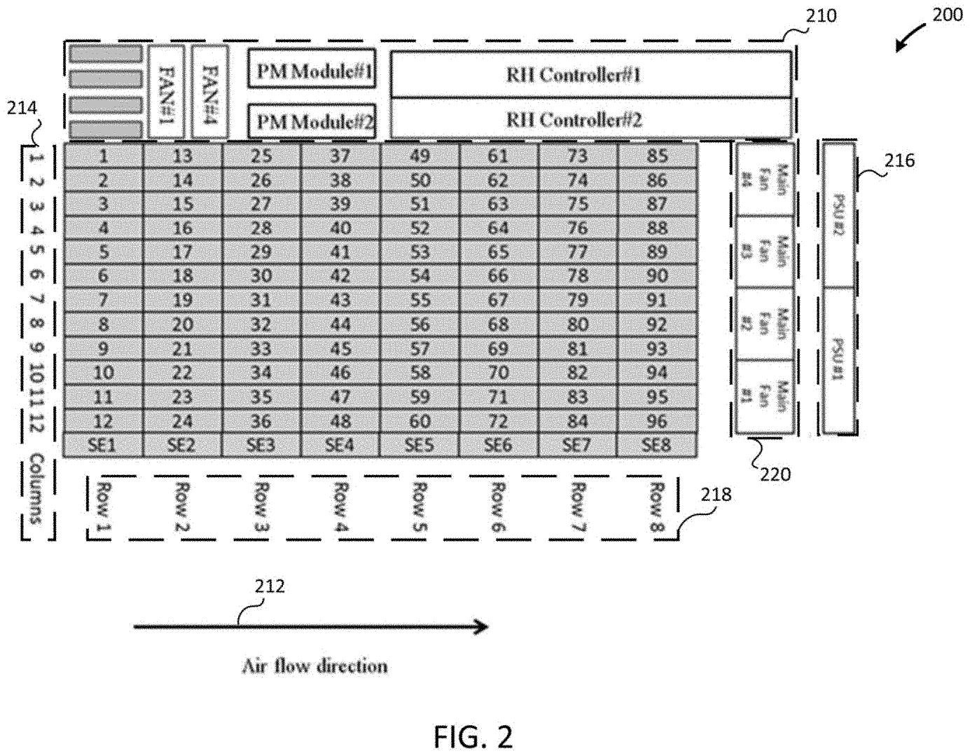

FIG. 2 is a schematic layout of another high-density computing enclosure 200 including a plurality of devices 1-96 arranged along an air flow path having an air flow direction 112, from Row 1 to Row 9.

Enclosure 200 can have similar features and aspects to enclosure 120 of FIG. 1. As with enclosure 120, in enclosure 200, the plurality of devices can be cooled by forced convection with the assistance of cooling fans 220, according to various embodiments. Additionally, computing systems can include fan control components 210, which can include a controller, such as controller 110 of FIG. 1. The enclosure 200 also preferably includes at least one power supply unit (PSU) 216, which can be operatively coupled to the fan speed control components 210, the devices, or one or more main fans 220, which can be similar to cooling fans 118 of FIG. 1.

With respect to the devices to be cooled during operation, the example of the high-density computing enclosure 200 can include devices numbered from 1-96 arranged in a grid according to rows 118 and columns 114. As shown, there are 12 columns and 8 rows of devices. As shown, air flow direction 212 shows that row 1 of devices (1-12 and SE1) will receive outside fresh air before row 2 of devices (13-24 and SE2), and so forth. In this way, row 8 of devices (85-96 and SE8) would receive moving air from forced convection after rows 1-7, and last as shown. As described above, the first row of devices to become stagnant or overheated would be the last row of device, i.e., the row of devices furthest along the air flow path defined by housing 200 and by air caused to be moved by cooling fans 220.

FIG. 2, as an alternative to the layout of FIG. 1 in one aspect, includes main (cooling) fans 220 located at an exit end, downstream of devices 114 within a respective air flow path that passes devices 1-96. The exit end can be located nearer to devices 85-96 and SE8, as shown, and an entry end can be located nearer to devices 1-12 and SE1, as shown. In high-density embodiments (high-density in terms of type and/or number of devices 114 per enclosure 200) embodiments may locate main fans 220 on the exit end in order to improve or achieve laminar airflow in the enclosure 200.

FIG. 3 is a flowchart of a process 300 of controlling cooling fan speed within an enclosure, according to various embodiments.

Process 300 can begin, and at operation 312 can receive parameters including, for example, device power, offset value, thermal design power, and/or current or past temperature that has been detected.

Following operation 312, at operation 314 dynamic power can be calculated based on the received parameters.

At operation 316, it can be determined whether any parameters have changed since a previous time. If it is determined at operation 316 that parameters have changed, then the process 300 can return to operation 312 by return operation 324, and the changed parameters can be received. If it is determined at operation 316 than no parameters have changed, at operation 318 the device's target optimized operating temperature value can be determined.

Following operation 318, and based on dynamic power and operating temperature value, a speed of at least one cooling fan can be adjusted at operation 320. Following the adjustment of the cooling fan speed at 320, it can be determined if the process 300 should repeat at operation 322. If yes, the process can return to operation 312 via repeat operation 326.

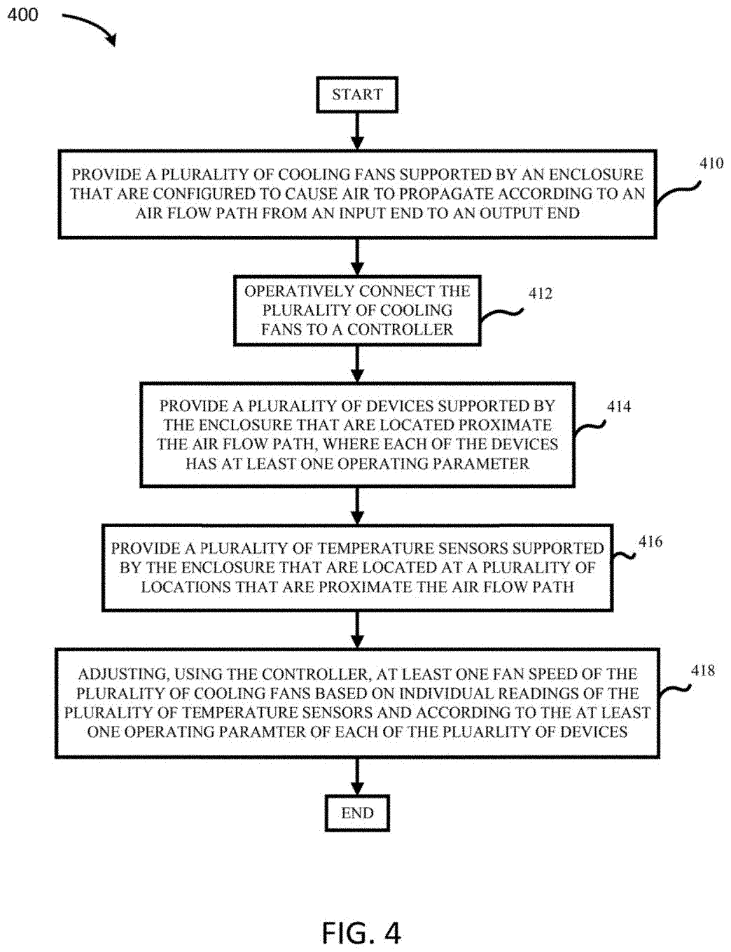

FIG. 4 is a flowchart of another process 400 of controlling cooling fan speed within an enclosure, according to various embodiments.

Process 400 can begin by providing a plurality of cooling fans supported by an enclosure at operation 410. The cooling fans can be configured to cause air to propagate according to an air flow path from an input end to an output end of the enclosure.

At operation 412, the plurality of cooling fans can be operatively connected to a controller. Following the operative connection at operation 412, a plurality of devices can be provided at operation 414 that are supported by the enclosure, the devices being proximate to the air flow path, where each of the devices has at least one operating parameter.

Following operation 414, a plurality of temperature sensors can be provided at operation 416 that are supported by the enclosure, and that are located at a plurality of locations that are proximate to the air flow path. After operation 416, at least one fan speed of the plurality of cooling fans can be adjusted using the controller based on individual readings of the plurality of temperature sensors and according to the at least one operating parameter of each of the plurality of devices. The process may then end or repeat.

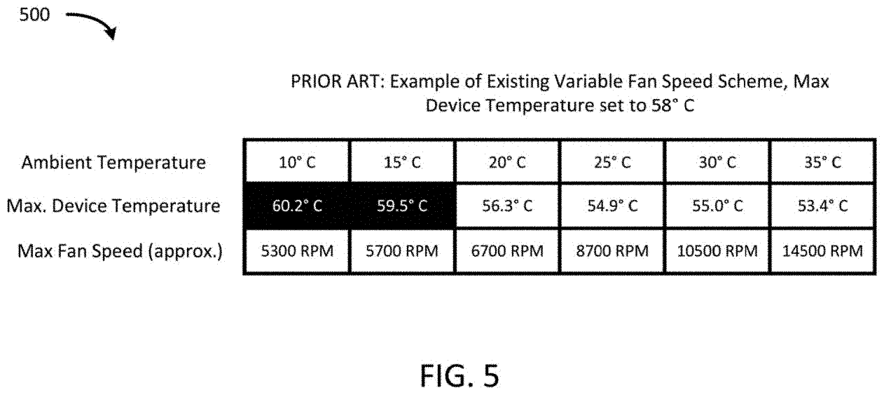

FIG. 5 is a graphical representation 500 of maximum device temperatures and corresponding fan speed at various ambient temperature representative of existing cooling fan control schemes.

Various ambient temperatures surround a computing enclosure. For example, shown at 500 are ambient temperatures of 10, 15, 20, 25, 30, and 35 degrees Celsius (° C.). At 20-35, the cooling fans operate sufficiently to cool the various devices below a predetermined maximum device temperature reading of 57° C. As can be seen, as fan speeds fall to 5,300 and 5,700 RPM for ambient temperatures 10 and 15° C., respectively, the maximum device temperature also exceeds the maximum device temperature of 57° C., which can lead to a variety of problems described herein. Therefore, there is a need according to the present disclosure to cause devices to the sufficiently cooled in particular at these lower ambient temperatures.

One solution to the problem displayed at 500 is to set a minimum floor RPM for all cooling fans for an enclosure, thus preventing too-low RPMs and device overheating. However, this can be power inefficient due to overcooling in some cases.

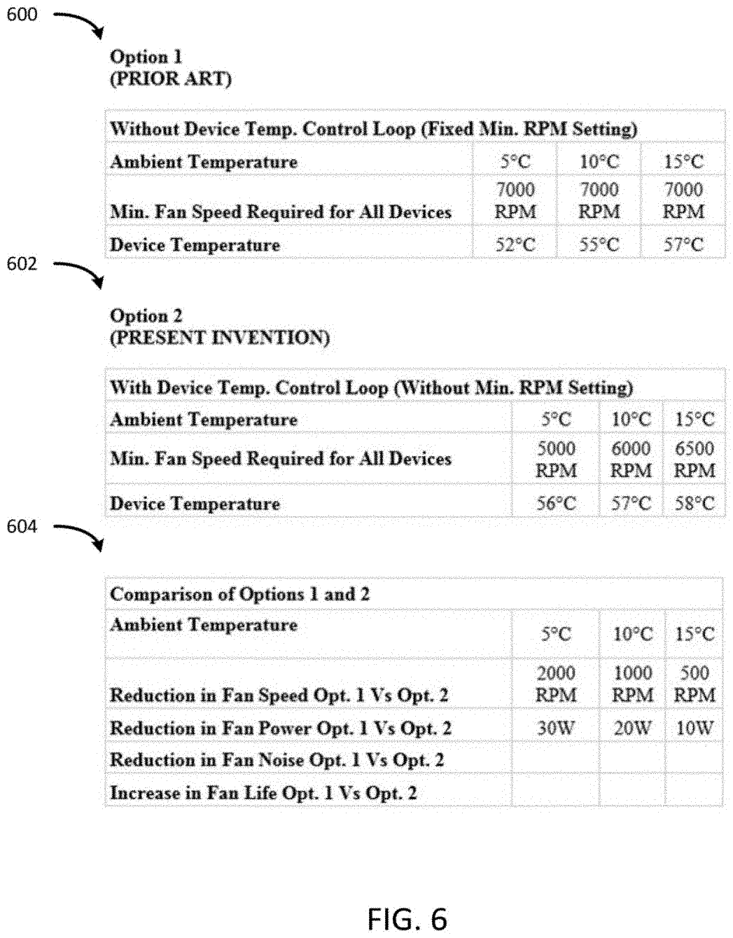

FIG. 6 shows graphical data of cooling fan schemes of the present disclosure as compared to an example prior art scheme.

At graph 600, a baseline fan control scheme according to fixed minimum RPM configuration of the prior art is shown. Without the device temperature control loop, a fixed minimum RPM setting can be employed for example ambient temperatures in a lower range, such as 5, 10, and 15° C. As with reference to FIG. 5, a maximum device temperature can be set at or determined to be about 58° C. As shown at graph 600, even at lower ambient temperatures, a 7,000 RPM fan speed floor during control allows the devices to run at proper temperature, and according to device VPD.

However, at graph 602, for the same ambient temperatures as graph 600, an embodiment of the present disclosure having a device temperature control loop without a minimum cooling fan RPM setting, the device temperatures remain at or below the VPD threshold of 58° C., yet the relative cooling fan RPMs are lower, with 5,000 RPM at 5, 6,000 RPM at 10, and 6,500 RPM at 15° C. ambient.

As shown with reference to graph 604, a reduction in fan speed of 2,000 RPM for 5° C., 1,000 RPM for 10° C., and 500 RPM for 15° C. were experienced by employing schemes according to the present disclosure. When the fan RPM are reduced by these amounts, it was found that a total system would also use less power, measured in Watts. For example, the reduction of 2,000 RPM at 5 degrees led to a 30 Watt reduction in power usage, the reduction of 1,000 RPM at 10 degrees led to a 20 W power use reduction, and at 15° C., the 500 RPM reduction led to a 10 W reduction is system power usage. In addition, a reduction in fan noise corresponding to the lower RPMs at the various temperatures was also observed, as was longer cooling fan life as a result of fewer fan rotations over time.

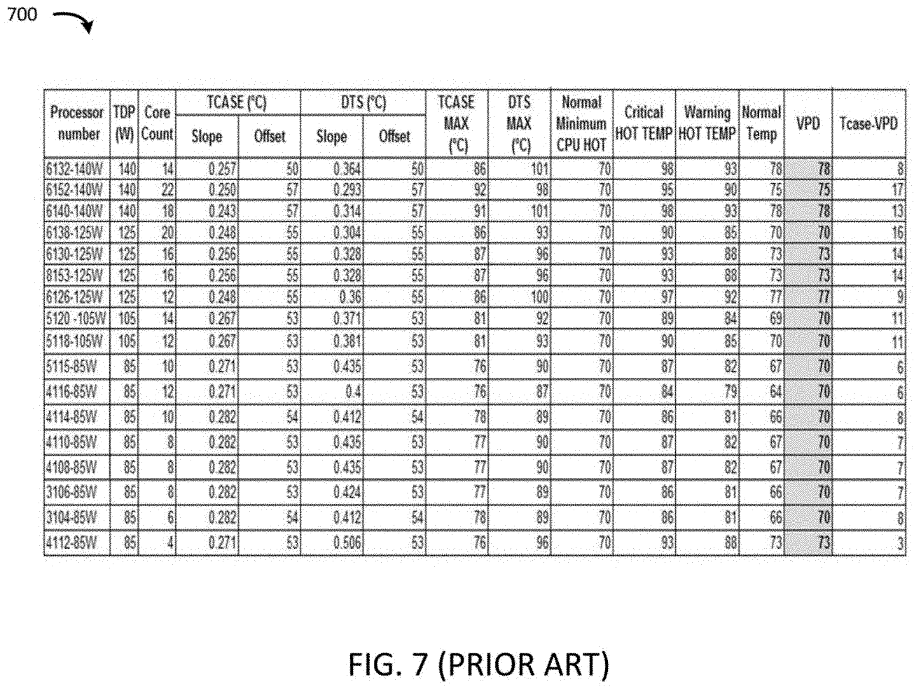

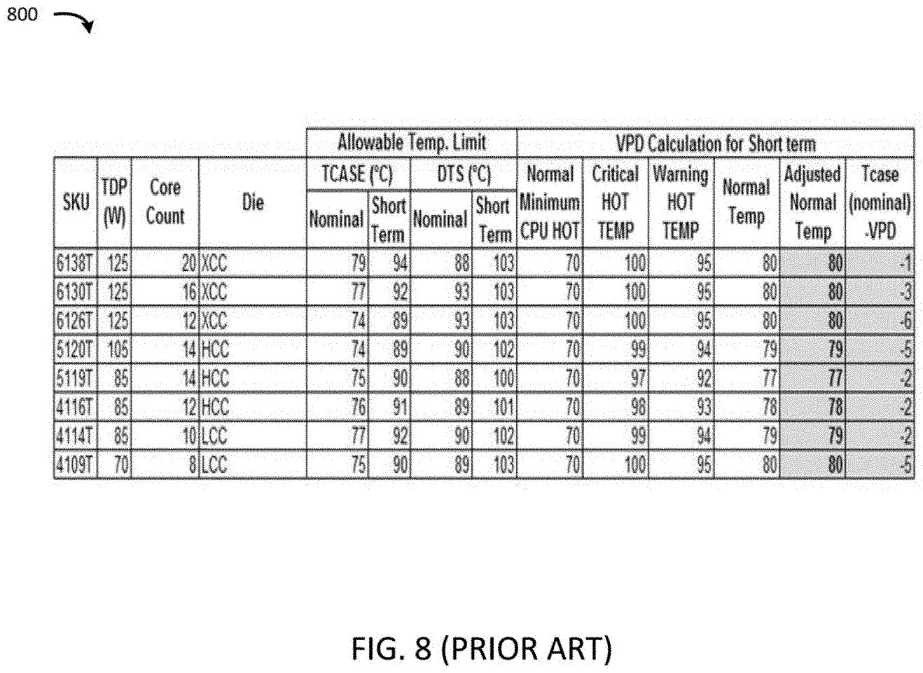

FIGS. 7 and 8 demonstrate and show a baseline of some example devices, and relevant data as exist in some existing schemes. In FIGS. 7 and 8, depicted devices are examples of CPUs, although other types of devices could produce similar results.

FIG. 7 shows an example data chart 700 for a variety of devices as they are used in existing schemes.

As shown with respect to data chart 700, devices (such as those used in the present disclosure) can include processors, which as shown, can range in power usage from 85 W to 140 W, and can vary in processor core count from 4 to about 22, although other processor types and power requirements can also utility the present disclosure. According to some embodiments, data chart 700 includes a list of possible CPUs, which can be generic in some examples.

In particular, data chart 700 shows that various thermal sensors can be located at or near various CPUs, such as on a CPU case (Tcase) (an allowable temperature for the CPU as measured on the CPU case) or inside a CPU itself (DTS for digital thermal sensor). By comparing Tcase to VPD of the CPU, it was be shown that values for Tcase-VPD can range from about 3 to about 17° C., in particular at higher power CPUs. Ideally, a VPD temperature value would always be lower than a CPU Tcase value, in order to achieve optimal CPU performance.

For certain CPUs, a target value (VPD) can be much less than a Tcase value. In other embodiments, it may be desirable to have a VPD only a degree Celsius or two below the Tcase maximum. In some embodiments, having a VPD and/or DTS value much different than the Tcase value can lead to higher fan speeds, more acoustic noise, and more power consumption in existing systems. Embodiments of the present disclosure make improvements to the problems in the existing art.

FIG. 8 shows an example data chart 800 for a variety of devices as they are used in existing schemes, with reference in particular to Network Equipment Building System (NEBS) CPUs.

For selected NEBS CPUs, data chart 800 demonstrate that, as presently exists, an adjusted normal temperature can be determined based on Tcase and DTS temperature readings. However, accurate assessment of CPU thermal status and needs for cooling leave room for improvement, as shown.

As shown, the target value (VPD) consistently comes higher than the CPU Tcase value. This can cause cooling fan speeds to decrease, but also can lead to a CPU exceeding its VPD and temperature limits, which can cause various performance and longevity problems for the CPU.

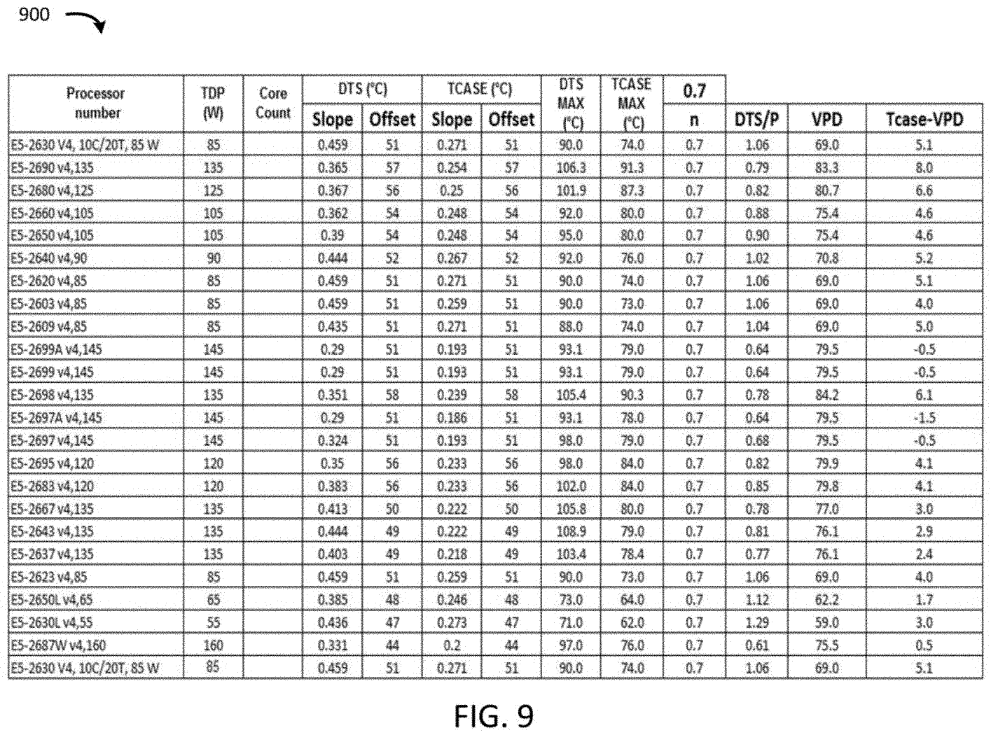

FIG. 9 shows an example data chart 900 for a new scheme of controlling cooling fans, according to embodiments of the present disclosure.

According to data chart 900 of FIG. 9, by employing embodiments of the present disclosure, an optimum target value for a CPU being cooled can be attained. Data chart 900 can result from an exponential equation (see e.g., FIG. 3 and accompanying description) to arrive at the optimal CPU and cooling fan speed values. According to some embodiments, an example exponential equation that can be used with respect to data chart 900 can calculate a target value based on input CPU offset, dynamic power, thermal design power, and digital thermal sensor (DTS) inputs. Based on the above inputs, the target value (here, for CPU) can be defined and/or determined as [(offset value)\hat{ }0.98*exponential(−Max DTS/(dynamic power\hat{ }2))]+(dynamic power\hat{ }0.7).

According to the data shown at data chart 900, the temperature values of each CPU are substantially closer to the Tcase value, and have substantially less deviation, as shown in particular with respect to the “Tcase-VPD” column of data chart 900. Therefore, as shown in FIG. 9, the present disclosure is substantially more efficient than the existing schemes of FIGS. 7 and 8.

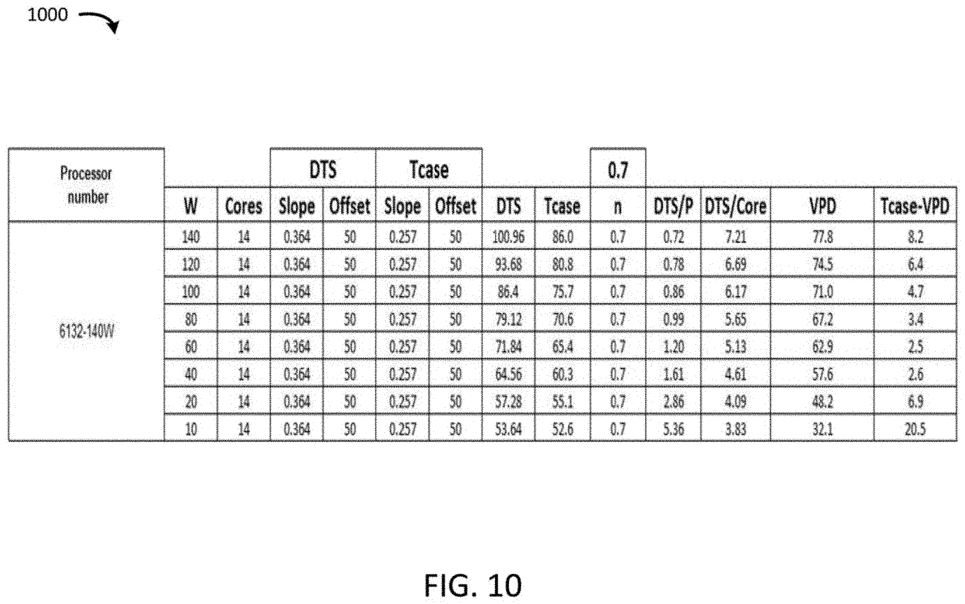

FIG. 10 shows an example data chart 1000 for a single CPU according to various embodiments of the present disclosure.

According to data chart 1000, it is shown how the methods and systems of the present disclosure operate to predict a target value with respect to dynamic power (e.g., DPD). According to data chart 1000, it is demonstrated that the present disclosure operates efficiently not only for maximum power, but also at various lesser power, CPU loads.

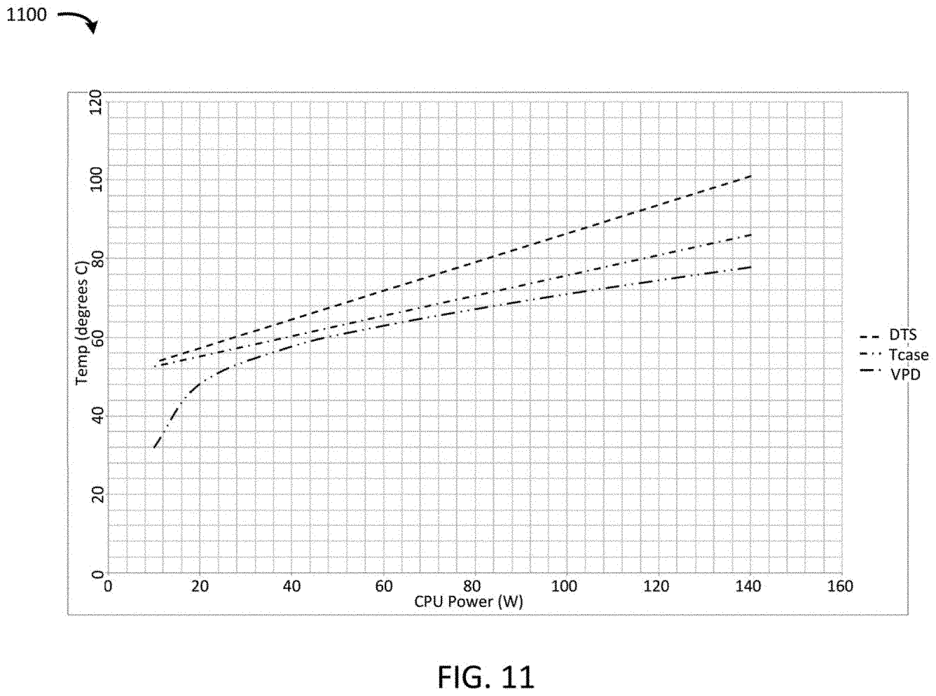

FIG. 11 is a comparative chart 1100 of DTS, Tcase, and VPD for a CPU at various power levels according to the data within data chart 1000 of FIG. 10. Chart 1100 shows relative temperature values and reading.

As shown, a line represents VPD in terms of CPU power on the X-axis, and temperature on the Y-axis. Likewise, an internal CPU power reading (DTS) is also shown, as is a CPU Tcase temperature reading, all shown concurrently to demonstrate that a particular CPU power usage leads to various DTS and Tcase values, with respect to the CPU VPD.

According to various embodiments, at any point in time, when a CPU is determined to have reached a target value (VPD), a controller can use a proportional-integral-derivative (PID) control loop to trigger and control a speed of one or more cooling fans, as described herein. When the CPU temperature is determined to exceed the VPD value, the fan speed would be caused to increase, and when the CPU temperature is determined to be lower than that VPD value, the fan speed would likewise be caused to decrease. As shown, the VPD values, according to the present disclosure, are located below the CPU allowable temperature graph shown as Tcase for any power dissipation (e.g., DPD), so that a CPU temperature can be maintained within the limit.

FIG. 12 is a block schematic diagram of a computer system 1200 according to embodiments of the present disclosure.

Computer system 1200, as shown, is configured with an interface 16 to enable controller 110 to receive a request to control fan speed for the cooling of one or more computing devices. A computer program product can be provided for controlling a plurality of cooling fans, comprising: a computer-readable storage device having a computer-readable program stored therein, where the computer-readable program, when executed on a computing device improves the computing device and causes the computing device to perform various methods described herein. An input 18 may be received at interface 16. In embodiments, the interface 16 can enable controller 110 to receive, or otherwise access, the input 18 via, for example, a network (e.g., an intranet, or a public network such as the Internet), or a storage medium, such as a disk drive internal or connected to controller 110. The interface can be configured for human input or other input devices, such as described later in regard to components of controller 110. It would be apparent to one of skill in the art that the interface can be any of a variety of interface types or mechanisms suitable for a computer, or a program operating in a computer, to receive or otherwise access or receive a source input or file.

Processors 12, 14 included in controller 110 are connected by a memory interface 22 to memory device or module 30. In embodiments, the memory 30 can be a cache memory, a main memory, a flash memory, or a combination of these or other varieties of electronic devices capable of storing information and, optionally, making the information, or locations storing the information within the memory 30, accessible to a processor. Memory 30 can be formed of a single electronic (or, in some embodiments, other technologies such as optical) module or can be formed of a plurality of memory devices. Memory 30, or a memory device (e.g., an electronic packaging of a portion of a memory), can be, for example, one or more silicon dies or chips, or can be a multi-chip module package. Embodiments can organize a memory as a sequence of bit, octets (bytes), words (e.g., a plurality of contiguous or consecutive bytes), or pages (e.g., a plurality of contiguous or consecutive bytes or words).

In embodiments, computer 1200 can include a plurality of memory devices. A memory interface, such as 22, between a one or more processors and one or more memory devices can be, for example, a memory bus common to one or more processors and one or more memory devices. In some embodiments, a memory interface, such as 22, between a processor (e.g., 12, 14) and a memory can be point to point connection between the processor and the memory, and each processor in the computer 1200 can have a point-to-point connection to each of one or more of the memory devices. In other embodiments, a processor (for example, 12) can be connected to a memory (e.g., memory 30) by means of a connection (not shown) to another processor (e.g., 14) connected to the memory (e.g., 22 from processor 14 to memory 30).

Computer 1200 can include an input/output (I/O) bridge 50, which can be connected to a memory interface 22, or to processors 12, 14. An I/O bridge 50 can interface the processors 12, 14 and/or memory devices 30 of the computer 1200 (or, other I/O devices) to I/O devices 60 connected to the I/O bridge 50. For example, controller 110 includes I/O bridge 50 interfacing memory interface 22 to I/O devices, such as I/O device 60. In some embodiments, an I/O bridge can connect directly to a processor or a memory, or can be a component included in a processor or a memory. An I/O bridge 50 can be, for example, a peripheral component interconnect express (PCI-Express) or other I/O bus bridge, or can be an I/O adapter.

An I/O bridge 50 can connect to I/O devices 60 through an I/O interface, or I/O bus, such as I/O bus (e.g., memory controller 22) of controller 110. For example, I/O bus can be a PCI-Express or other I/O bus. I/O devices 60 can be any of a variety of peripheral I/O devices or I/O adapters connecting to peripheral I/O devices. For example, I/O device 60 can be a graphics card, keyboard or other input device, a hard disk drive (HDD), solid-state drive (SSD) or other storage device, a network interface card (NIC), etc. I/O devices 60 can include an I/O adapter, such as a PCI-Express adapter, that connects components (e.g., processors or memory devices) of the computer 1200 to various I/O devices 60 (e.g., disk drives, Ethernet networks, video displays, keyboards, mice, styli, touchscreens, etc.).

Computer 1200 can include instructions 42 executable by one or more of the processors 12, 14 (or, processing elements, such as threads of a processor). The instructions 42 can be a component of one or more programs. The programs, or the instructions 30, can be stored in, and/or utilize, one or more memory devices of computer 1200. Memory 30 can also store one or more instruction output 44. As illustrated in the example of FIG. 12, controller 110 includes a plurality of programs or modules, such as temperature sensor module 6, fan speed module 9, power dissipation module 5, dynamic airflow module 7, device parameters module 3, and ambient temperature module 11. A program can be, for example, an application program, an operating system (OS) or a function of an OS, or a utility or built-in function of the computer 1200. A program can be a hypervisor, and the hypervisor can, for example, manage sharing resources of the computer 1200 (e.g., a processor or regions of a memory, or access to an I/O device) among a plurality of programs or OSes.

Programs can be “stand-alone” programs that execute on processors and use memory within the computer 1200 directly, without requiring another program to control their execution or their use of resources of the computer 1200. For example, controller 110 includes (optionally) stand-alone programs in temperature sensor module 6, fan speed module 9, power dissipation module 5, dynamic airflow module 7, device parameters module 3, and ambient temperature module 11. A stand-alone program can perform particular functions within the computer 1200, such as controlling, or interfacing (e.g., access by other programs) an I/O interface or I/O device. A stand-alone program can, for example, manage the operation, or access to, a memory (e.g., memory 30). A basic I/O subsystem (BIOS), or a computer boot program (e.g., a program that can load and initiate execution of other programs) can be a standalone program.

Controller 110 within computer 1200 can include one or more OS 2, and an OS 2 can control the execution of other programs such as, for example, to start or stop a program, or to manage resources of the computer 1200 used by a program. For example, controller 110 includes OS 2, which can include, or manage execution of, one or more programs, such as OS 2 including (or, managing) fan interface module 8 and device interface module 4. In some embodiments, an OS 2 can function as a hypervisor.

A program can be embodied as firmware (e.g., BIOS in a desktop computer, or a hypervisor) and the firmware can execute on one or more processors and, optionally, can use memory, included in the computer 1200. Firmware can be stored in a memory (e.g., a flash memory) of the computer 1200. For example, controller 110 includes firmware 40 stored in memory 30. In other embodiments, firmware 40 can be embodied as instructions (e.g., comprising a computer program product) on a storage medium (e.g., a CD-ROM, DVD-ROM, flash memory, or disk drive), and the computer 1200 can access the instructions from the storage medium.

In embodiments of the present disclosure, computer 1200 can include instructions for dynamic cooling fan control. Controller 110 includes, for example, temperature sensor module 6, fan speed module 9, power dissipation module 5, dynamic airflow module 7, device parameters module 3, and ambient temperature module 11, which can operate, in conjunction with fan interface module 8 and device interface module 4 for cooling fan control. The computer 1200 can utilize temperature sensor module 6, fan speed module 9, power dissipation module 5, dynamic airflow module 7, device parameters module 3, and ambient temperature module 11, which can operate, in conjunction with fan interface module 8 and device interface module 4 for cooling fan control in a memory 30 of the computer 1200, such as controller 110 storing the various temperature and device characteristics and parameter data in memory 30.

The example computer system 1200 and controller 110 are not intended to limiting to embodiments. In embodiments, computer system 1200 can include a plurality of processors, interfaces, and inputs and can include other elements or components, such as networks, network routers or gateways, storage systems, server computers, virtual computers or virtual computing and/or I/O devices, cloud-computing environments, and so forth. It would be evident to one of skill in the art to include a variety of computing devices interconnected in a variety of manners in a computer system embodying aspects and features of the disclosure.

In embodiments, controller 110 can be, for example, a computing device having a processor (e.g., 12) capable of executing computing instructions and, optionally, a memory 30 in communication with the processor. For example, controller 110 can be a desktop or laptop computer; a tablet computer, mobile computing device, personal digital assistant (PDA), or cellular phone; or, a server computer, a high-performance computer (HPC), or a super computer. Controller 110 can be, for example, a computing device incorporated into a wearable apparatus (e.g., an article of clothing, a wristwatch, or eyeglasses), an appliance (e.g., a refrigerator, or a lighting control), a mechanical device, or (for example) a motorized vehicle. It would be apparent to one skilled in the art that a computer embodying aspects and features of the disclosure can be any of a variety of computing devices having processors and, optionally, memory devices, and/or programs. Controller 110 and/or the control module 208 can be operatively connected to the enclosure and cooling fan based system described with respect to FIGS. 1 and 2, above. The controller 110 can also be operably connected to read or control the cooling fan and device temperature reading feedback and among other feedback, as appropriate.

It is understood that numerous variations of cooling fan control could be made while maintaining the overall inventive design of various components thereof and remaining within the scope of the disclosure. Numerous alternate design or element features have been mentioned above.

As used herein, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Unless otherwise indicated, all numbers expressing feature sizes, amounts, and physical properties are to be understood as being modified by the term “about.” Accordingly, unless indicated to the contrary, the numerical parameters set forth are approximations that can vary depending upon the desired properties sought to be obtained by those skilled in the art utilizing the teachings disclosed herein.

Reference is made herein to the accompanying drawings that form a part hereof and in which are shown by way of illustration at least one specific embodiment. The detailed description provides additional specific embodiments. It is to be understood that other embodiments are contemplated and may be made without departing from the scope or spirit of the present disclosure. The detailed description, therefore, is not to be taken in a limiting sense. While the present disclosure is not so limited, an appreciation of various aspects of the invention will be gained through a discussion of the examples provided.

What is claimed is:

1. A system, comprising:
an enclosure defining an air flow path having an input end and an output end;
a plurality of devices operatively supported by the enclosure and located proximate the air flow path, each of the devices having at least one operating parameter;
a plurality of cooling fans supported by the enclosure that are configured to cause air to propagate according to the air flow path from the input end to the output end;
a plurality of temperature sensors supported by the enclosure that are located at a plurality of locations that are proximate the air flow path; and
a controller configured to adjust at least one fan speed of the plurality of cooling fans based on individual readings of the plurality of temperature sensors and according to the at least one operating parameter of each of the plurality of devices.

2. The system of claim 1, wherein the at least one operating parameter is a temperature-related parameter.

3. The system of claim 2, wherein the temperature-related parameter is a maximum operating temperature parameter according to at least one of the plurality of devices.

4. The system of claim 1, wherein the input end is configured to receive air from outside the enclosure as an air intake.

5. The system of claim 4, wherein the output end is configured to expel air to outside the enclosure, and wherein the input end is configured to receive air that is relatively cooler than air that is expelled at the output end.

6. The system of claim 1, wherein the air flow path has a start point at the input end and has an end point at the output end, wherein the start point is relatively cooler and the end point is relatively warmer.

7. The system of claim 6, wherein a first device of the plurality of devices is located proximate the start point, a second device of the plurality of devices is located proximate the end point, and wherein the first device operates at a lower temperature than the second device.

8. The system of claim 1, wherein the controller is further configured to:
determine a minimum fan speed for each cooling fan of the plurality of cooling fans, and
selectively control the plurality of cooling fans such that each cooling fan maintains a speed at or above the minimum fan speed for each cooling fan.

9. The system of claim 1, wherein the controller utilizes a controller loop to control operation of at least one of the plurality of devices, and wherein at least one operating parameter is a dynamic power dissipation parameter.

10. The system of claim 9, wherein the controller further utilizes the dynamic power dissipation parameter to control the operation of the at least one of the plurality of devices.

11. The system of claim 1, wherein the controller is further configured to seamlessly adjust the at least one fan speed upon the plurality of devices being removed and replaced with a second, different plurality of devices.

12. A method of controlling a plurality of cooling fans, comprising:
providing a plurality of cooling fans supported by an enclosure that are configured to cause air to propagate according to an air flow path from an input end to an output end;
operatively connecting the plurality of cooling fans to a controller;
providing a plurality of devices supported by the enclosure that are located proximate the air flow path, wherein each of the devices has at least one operating parameter;
providing a plurality of temperature sensors supported by the enclosure that are located at a plurality of locations that are proximate the air flow path; and
adjusting, using the controller, at least one fan speed of the plurality of cooling fans based on individual readings of the plurality of temperature sensors and according to the at least one operating parameter of each of the plurality of devices.

13. The method of claim 12, wherein the at least one operating parameter is a temperature-related parameter.

14. The method of claim 13, wherein the temperature-related parameter is a maximum operating temperature parameter according to at least one of the plurality of devices.

15. The method of claim 12, wherein the air flow path has a start point at the input end and has an end point at the output end, wherein the start point is relatively cooler and the end point is relatively warmer, and wherein a first device of the plurality of devices is located proximate the start point, a second device of the plurality of devices is located proximate the end point, and wherein the first device operates at a lower temperature than the second device.

16. The method of claim 12, further comprising:
determining a minimum fan speed for each cooling fan of the plurality of cooling fans, and
selectively controlling the plurality of cooling fans such that each cooling fan maintains a speed at or above the minimum fan speed for each cooling fan.

17. The method of claim 12, wherein at least one operating parameter is a dynamic power dissipation parameter, and wherein the controller further utilizes the dynamic power dissipation parameter to control the operation of the at least one of the plurality of devices.

18. A computer program product for controlling a plurality of cooling fans, the computer program product comprising a computer-readable storage medium having program code embodied therewith, the program code comprising computer-readable program code configured to perform a method, comprising:
providing a plurality of cooling fans supported by an enclosure that are configured to cause air to propagate according to an air flow path from an input end to an output end;
operatively connecting the plurality of cooling fans to a controller;
providing a plurality of devices supported by the enclosure that are located proximate the air flow path, wherein a controller loop is utilized to control operation of at least one of the plurality of devices, wherein each of the devices has at least one operating parameter, and wherein at least one operating parameter is a dynamic power dissipation parameter;
providing a plurality of temperature sensors supported by the enclosure that are located at a plurality of locations that are proximate the air flow path; and
adjusting, using the controller, at least one fan speed of the plurality of cooling fans based on individual readings of the plurality of temperature sensors and according to the at least one operating parameter of each of the plurality of devices,

19. The computer program product of claim 18, wherein the at least one operating parameter is a temperature-related parameter, and wherein the temperature-related parameter is a maximum operating temperature parameter according to at least one of the plurality of devices.

20. The computer program product of claim 18, wherein the method further comprises:
determining a minimum fan speed for each cooling fan of the plurality of cooling fans, and
selectively controlling the plurality of cooling fans such that each cooling fan maintains a speed at or above the minimum fan speed for each cooling fan.
